(19) United States
(12) Patent Application Publication
(10) Pub. No.: US 2026/0164861 A1
(43) Pub. Date: Jun. 11, 2026

(54) Light Emitting Element and Display Device Including the Same

(71) Applicant: LG Display Co., Ltd., Seoul (KR)

(72) Inventors: Jinhwa Shin, Suwon-si (KR); Hansaem Kang, Goyang-si (KR); Jongmin Jang, Hwaseong-si (KR)

(21) Appl. No.: 19/185,870

(22) Filed: Apr. 22, 2025

(30) Foreign Application Priority Data
Dec. 6, 2024 (KR) 10-2024-0180336

(51) Int. Cl. H10H 20/819; H10H 20/84; H10H 29/49

(52) U.S. Cl. CPC H10H 20/819; H10H 20/84; H10H 29/49

(57) ABSTRACT

The present disclosure relates to a light-emitting element and a display device including the same in which it is possible to prevent the occurrence of a transfer defect due to bonding error between a light-emitting element and a display panel during a transfer process. To achieve this, in a light-emitting element, by sequentially arranging a first semiconductor layer, an active layer, and a second semiconductor layer between a first electrode disposed at a lowermost portion and a second electrode disposed at an uppermost portion, forming an uneven pattern at each of contacting portions of the second electrode and the second semiconductor layer, and also forming an uneven pattern on an upper surface of the second electrode, it is possible to further increase a current injection area by the uneven pattern compared to conventional models, thereby expanding a light-emitting area and improving luminance.

### CROSS REFERENCE TO RELATED APPLICATION

Pursuant to 35 U.S.C. § 119(a), this application claims the benefit of an earlier filing date and right of priority to Republic of Korea Patent Application No. 10-2024-0180336 filed on Dec. 6, 2024, which is hereby incorporated by reference in their entirety.

### TECHNICAL FIELD

The present disclosure relates to a light-emitting element and a display device including the same, and more specifically, to a light-emitting diode (LED) of an inorganic material and a display device including the same.

### BACKGROUND

Recently, display devices including a light-emitting diode (LED) have been attracting attention as next-generation display devices. Since an LED is formed of an inorganic material rather than an organic material, the display devices including the LED have a faster turn-on speed, better luminous efficiency, and higher luminance images than LCD devices or OLED display devices.

These LEDs are disposed on a donor member on the basis of a package during a transfer process, detached from the donor member as the basis of a package, and transferred onto a display panel through a transfer member.

However, to increase the luminous efficiency of the light-emitting elements, it is important to secure a light-emitting area by increasing a current injection area. However, a stamp transfer method using an electrostatic force (hereinafter referred to as ESC-F) and van der Waals' force (hereinafter referred to as VDW-F) is affected by pick up and place processes as a contact area and force are proportional to each other. During the pickup and place process, there is a problem that a transfer defect occurs on a panel when a bonding force between the transfer member and the light-emitting element is greater than a bonding force between the display panel and the light-emitting element

### SUMMARY

Accordingly, to solve the above problems, the inventors of the present disclosure have invented a light-emitting element and a display device including the same in which it is possible to prevent or at least reduce a transfer defect from occurring due to a bonding error between a light-emitting element and a display panel during a transfer process.

Implementations of the present disclosure are directed to providing a light-emitting element and a display device including the same in which a contact (current injection) area can be adjusted so that a bonding force between a light-emitting element and a transfer member is smaller than a bonding force between the light-emitting element and the panel during a transfer process.

Objects of the present disclosure are not limited to the above-described objects, and other objects and advantages of the present disclosure that are not mentioned can be understood by the following description and more clearly understood by implementations of the present disclosure. In addition, it can be easily seen that the objects and advantages of the present disclosure can be achieved by means as stated in the claims and a combination thereof.

In a light-emitting element according to one embodiment of the present disclosure, a first semiconductor layer, an active layer, and a second semiconductor layer may be sequentially disposed between a first electrode disposed at a lowermost portion and a second electrode disposed at an uppermost portion, an uneven pattern may be formed at each of contacting portions of the second electrode and the second semiconductor layer, and an uneven pattern may also be formed on an upper surface of the second electrode.

In addition, in a light-emitting element according to another embodiment of the present disclosure, a second semiconductor layer may be disposed on a second electrode, an active layer may be disposed on the second semiconductor layer, a first semiconductor layer may be disposed on the active layer, a first electrode may be disposed under one side of the first semiconductor layer, and an uneven pattern formed by alternating a concave shape and a convex shape may be disposed on an upper portion of the first semiconductor layer, which is an uppermost layer.

In addition, in a display device according to still another embodiment of the present disclosure, a plurality of light-emitting element in which a first uneven pattern is formed on an upper portion of a second semiconductor layer in contact with a second electrode, a second uneven pattern is formed on a lower portion of the second electrode corresponding to the first uneven pattern, and a third uneven pattern is formed on an upper portion of the second electrode may be bonded to a display panel through a first bonding electrode in electrical contact with the first electrode and a second bonding electrode electrically connected to a first connection electrode disposed on side surfaces and an upper surface of a bank layer through a plurality of through holes, respectively, and an uneven pattern may be formed at a portion of the second connection electrode disposed to continuously extend on the plurality of light-emitting elements, the portion being in contact with the second electrode.

### BRIEF DESCRIPTION OF DRAWINGS

FIG. 1 is a schematic view illustrating a configuration of a light-emitting element according to an embodiment of the present disclosure.

FIG. 2 is a cross-sectional view of a display device to which a plurality of light-emitting elements according to an embodiment of the present disclosure are applied.

FIG. 3 is a cross-sectional view of the display device to which the light-emitting element according to an embodiment of the present disclosure is applied.

FIG. 4 is a view illustrating an example in which the light-emitting element according to an embodiment of the present disclosure is picked up from a donor member by a transfer member.

FIG. 5 is a view illustrating an example in which the light-emitting element according to an embodiment of the present disclosure is placed on the display panel by the transfer member.

FIG. 6 is a view illustrating an example of a configuration of a light-emitting element according to another embodiment of the present disclosure.

FIGS. 7A to 7C, 8A to 8C, 9A to 9C, and 10A to 10C are views illustrating transfer processes of the light-emitting element according to an embodiment of the present disclosure.

FIG. 11 is a graph illustrating luminance according to the amount of current when an uneven structure is applied to an electrode of the light-emitting element according to an embodiment of the present disclosure.

### DETAILED DESCRIPTION

Advantages and features of the present disclosure and methods for achieving them will become clear with reference to implementations described below in detail in conjunction with the accompanying drawings. However, the present disclosure is not limited to implementations to be disclosed below but may be implemented in various different forms, these implementations are merely provided to make the disclosure of the present disclosure complete and fully inform those skilled in the art to which the present disclosure pertains of the scope of the present disclosure, and the present disclosure is only defined by the scope of the appended claims.

Since shapes, sizes, ratios, angles, numbers, etc. disclosed in the drawings for describing the implementations of the present disclosure are exemplary, the present disclosure is not limited to the illustrated items. The same reference number denotes the same components throughout the disclosure. In addition, in describing the present disclosure, when it is determined that the detailed description of a related known technology may unnecessarily obscure the gist of the present disclosure, the detailed description thereof will be omitted. When “comprises,” “has,” “includes,” etc. described in the present disclosure are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description related to the margin of error.

When the positional relationship is described, for example, when the positional relationship between two parts is described using “on,” “above,” “under,” “next to,” or the like, “ ” one or more other parts may be located between the two parts unless “immediately” or “directly” is used.

When the temporal relationship is described, when the temporal relationship is described using the term “after,” “subsequently,” “then,” “before,” or the like, it may also include a non-consecutive case unless the term “immediately” or “directly” is used.

Although terms such as first and second are used to describe various components, these components are not limited by these terms. These terms are only used to distinguish one component from another component. Therefore, a first component described below may be a second component within the technical spirit of the present disclosure.

In the description of the components of the present disclosure, terms such as first A, B, (a), (b), etc. may be used. These terms are only for the purpose of distinguishing one component from another component, and the nature, sequence, order, or the like of the corresponding component is not limited by these terms. When a certain component is described as being “connected,” “coupled,” or “joined” to another component, the certain component may be connected or joined directly to another component, but it should be understood that other components may be “interposed” between the components, which may be connected or coupled indirectly, unless otherwise stated specially.

It should be understood that the term “at least one” includes any combination of one or more of associated components. For example, the term “at least one of first, second, and third components” may include not only the first, second, or third component, but also any combination of two or more of the first, second, and third components.

In the present disclosure, “device” may include a display device, such as a liquid crystal module (LCM) and an organic light-emitting display module (OLED module), including a display panel and a driver for driving the display panel. In addition, the device may also include a set electronic device or a set device (or a set device), such as a laptop computer, a television, a computer monitor, a vehicle or automotive device, a mobile electronic device of a smartphone, an electronic pad, etc., which is a complete product or final product including an LCM, an OLED, etc.

Accordingly, the device in the present disclosure may include a display device, such as an LCM or OLED module, and a set device that is an application product or end-consumer device including an LCM or OLED module, etc.

In addition, in some implementations, a LCM or an OLED module that are composed of a display panel, a driving unit, etc. may be referred to as a “display device,” and an electronic device as a finished product including an LCM or OLED module may be separately referred to as a “set device.” For example, the display device may include a display panel of an LCD or an OLED, and a source printed circuit board (PCB) as a control unit for driving the display panel. The set device may further include a set PCB as a set control unit electrically connected to the source PCB to drive the entirety of the set device.

The display panel used in the implementations of the present disclosure may be any type of display panel, such as an OLED display panel, an electroluminescent display panel, etc. Implementations are not limited thereto. For example, the display panel may be a display panel that may generate sound by being vibrated by a vibration device according to the embodiment of the present disclosure. The shape or size of the display panel applied to the display device according to implementations of the present disclosure is not limited.

The respective features of various implementations of the present disclosure may be coupled or combined partially or entirely, various technological interworking and driving are made possible, and the implementations may be implemented independently of each other or implemented together in an associated relationship.

Hereinafter, implementations of the present disclosure will be described with reference to the accompanying drawings and implementations as follows. Scales of components illustrated in the drawings differ from the actual scale for convenience of description, and thus are not limited to the scales illustrated in the drawings.

Hereinafter, as one embodiment of the present disclosure, a display device using a micro LED as a light-emitting element will be described.

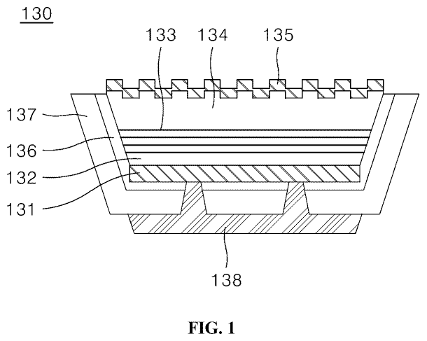

FIG. 1 is a schematic view illustrating a configuration of a light-emitting element according to an embodiment of the present disclosure.

Referring to FIG. 1, a light-emitting element 130 according to the embodiment of the present disclosure may include a first electrode 131, a first semiconductor layer 132 disposed on the first electrode 131, an active layer 133 disposed on the first semiconductor layer 132, a second semiconductor layer 134 disposed on the active layer 133, and a second electrode 135 disposed on the second semiconductor layer 134.

A first uneven pattern may be formed on an upper portion of the second semiconductor layer 134 in contact with the second electrode 135, a second uneven pattern may be formed on a lower portion of the second electrode 135 corresponding to the first uneven pattern, and a third uneven pattern may be formed on an upper portion of the second electrode 135.

Each of the first uneven pattern, the second uneven pattern, and the third uneven pattern may be formed by alternating concave and convex shapes.

In addition, the light-emitting element 130 may further include a first passivation layer 136 disposed under the first electrode 131, a second passivation layer 137 disposed under the first passivation layer 136, and a first bonding electrode 138 disposed under the second passivation layer 137.

The first passivation layer 136 may have a structure that extends upward from both ends and surrounds outer edges of the first semiconductor layer 132, the active layer 133, and the second semiconductor layer 134. The first passivation layer 136 may serve as a sidewall that protects the active layer 133 and may include, for example, a material, such as aluminum oxide (Al2O3), hafnium oxide (HfO2), etc.

The second passivation layer 137 may have a structure that extends upward from both ends and surrounds the outer edge of the first passivation layer 136. The second passivation layer 137 can prevent a P-pad metal material from migrating to the active layer 133 and double-protect the sidewall. The second passivation layer 137 may include, for example, a material, such as silicon oxide (SiO2), silicon nitride (SiNx), etc.

The first bonding electrode 138 may come into electrical contact with the first electrode 131 through a plurality of through holes.

One of the first semiconductor layer 132 and the second semiconductor layer 134 may be a semiconductor layer doped with an N-type impurity, and the other may be a semiconductor layer doped with a P-type impurity.

The active layer 133 may include a multi-quantum well (MQW) structure having a well layer and a barrier layer having a higher band gap than the well layer.

Each of the first electrode 131 and the second electrode 135 may be formed of one of indium tin oxide (ITO), indium zinc oxide (IZO), and indium gallium zinc oxide (IGZO). For example, the first electrode 131 may be an anode electrode, and the second electrode 135 may be a cathode electrode.

The first passivation layer 136 and the second passivation layer 137 may be formed of an insulation material including silicon nitride (SiNx) or silicon oxide (SiOx).

The first passivation layer 136 and the second passivation layer 137 may have a structure in which a reflective material is dispersed in a resin layer.

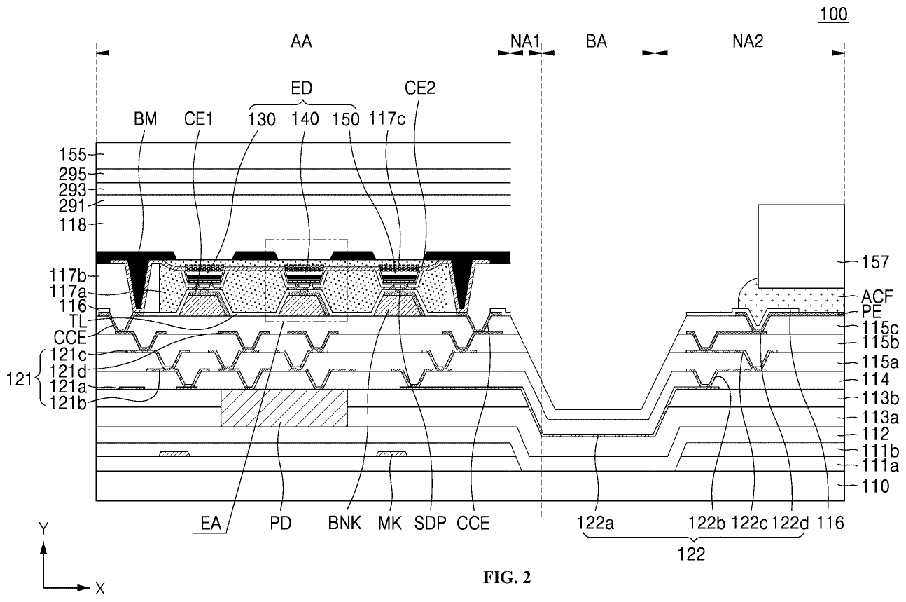

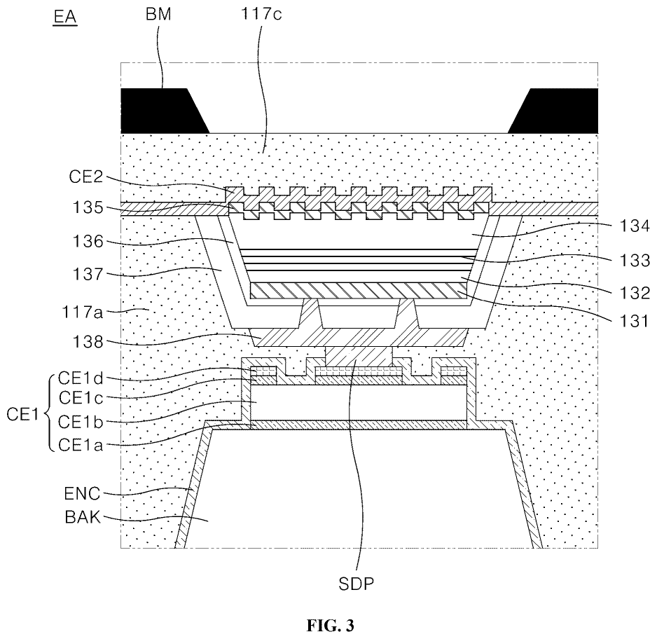

FIG. 2 is a cross-sectional view of a display device to which a plurality of light-emitting elements according to an embodiment of the present disclosure are applied. FIG. 3 is a cross-sectional view of the display device to which the light-emitting element according to an embodiment of the present disclosure is applied. For example, FIG. 2 is a cross-sectional view of an active area AA, a first non-active area NA1, a bending area BA, and a second non-active area NA2. For example, FIG. 3 is a cross-sectional view of the active area including one light-emitting unit EA.

Referring to FIGS. 2 and 3, a display device 100 according to the embodiment of the present disclosure includes a display panel to which the light-emitting element 130 having the above structure of FIG. 1 is bonded, and a first bonding electrode 138 may be bonded to a second bonding electrode SDP of the display panel.

A bank layer BNK may be disposed on a third insulating layer 115c. The bank layer BNK may be formed of an organic insulation material. The bank layer BNK may be formed of a single layer or multiple layers of an organic insulation material. For example, the bank layer BNK may be formed of a photo resist, polyimide (PI), or acrylic-based material, but the implementations of the present disclosure are not limited thereto.

The light-emitting element 130 may be disposed on the bank layer BNK. For example, the light-emitting element 130 may have a first connection electrode CE1 disposed on the bank layer BNK, a second bonding electrode SDP disposed on the first connection electrode CE1, and the first bonding electrode 138 of the light-emitting element 130 disposed on the second bonding electrode SDP.

The first connection electrode CE1 may be disposed on the bank layer BNK. The first connection electrode CE1 may be electrically connected to one of a plurality of signal lines TL. At least a part of the first connection electrode CE1 may extend outward from the bank layer BNK and may be electrically connected to the signal line TL closest to the first connection electrode CE1.

The first connection electrode CE1 may be electrically connected to the first electrode 131 of the light-emitting element 130 and may transmit an anode voltage output from a pixel driving circuit PD to the light-emitting element ED through the signal line TL. A different voltage may be applied to the first connection electrode CE1 of each of the plurality of light-emitting elements according to an image, which will be displayed. For example, a different voltage may be applied to the first connection electrode CE1 of each of the plurality of light-emitting elements. Accordingly, the first connection electrode CE1 may be a pixel electrode, and the implementations of the present disclosure are not limited thereto.

The first connection electrode CE1 may be formed of a conductive material. For example, the first connection electrode CE1 may be formed integrally with the plurality of signal lines. For example, the first connection electrode CE1 may be formed of the same conductive material as the plurality of signal lines, but the implementations of the present disclosure are not limited thereto. For example, the first connection electrode CE1 may be formed of a conductive material, such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the implementations of the present disclosure are not limited thereto. As another example, the first connection electrode CE1 may be formed of a conductive multilayered structure. For example, the plurality of first connection electrodes CE1 may be formed of a multilayered structure of titanium (Ti)/aluminum (Al)/titanium (Ti)/indium tin oxide (ITO), but the implementations of the present disclosure are not limited thereto.

The second bonding electrode SDP may be referred to as a solder pattern SDP because a part thereof is melted and has a bonding function. The second bonding electrode SDP may be eutectic-bonded to the first bonding electrode 138. The bank layer BNK may be disposed under the second bonding electrode SDP.

A first optical layer 117a may be disposed to surround the light-emitting element 130, the bank layer BNK, and the first connection electrode CE1. For example, the first optical layer 117a may be a diffusion layer, a sidewall diffusion layer, etc., but the implementations of the present disclosure are not limited thereto.

The second optical layer 117b may be disposed to surround the first optical layer 117a. For example, the second optical layer 117b may contact with side surfaces of the first optical layer 117a. For example, the second optical layer 117b may be disposed in an area between the plurality of light-emitting elements. However, the implementations of the present disclosure are not limited thereto. For example, the second optical layer 117b may be a diffusion layer, a diffusion layer window, a window diffusion layer, etc., but the implementations of the present disclosure are not limited thereto.

The plurality of light-emitting elements ED may be one of an LED or a micro LED, but the implementations of the present disclosure are not limited thereto. The plurality of light-emitting elements ED may be disposed on the bank layer BNK and the first connection electrode CE1. The plurality of light-emitting elements ED may be disposed on the first connection electrode CE1 and may be electrically connected to the first connection electrode CE1. Accordingly, the light-emitting element ED may receive the anode voltage output from the pixel driving circuit PD through the signal line TL and the first connection electrode CE1 and emit light.

The plurality of light-emitting elements ED may include a first light-emitting element 130, a second light-emitting element 140, and a third light-emitting element 150. The first light-emitting element 130 may be disposed in a first sub-pixel. The second light-emitting element 140 may be disposed in a second sub-pixel. The third light-emitting element 150 may be disposed in a third sub-pixel. For example, one of the first light-emitting element 130, the second light-emitting element 140, and the third light-emitting element 150 may be a red light-emitting element, another may be a green light-emitting element, and the remaining one may be a blue light-emitting element, but the implementations of the present disclosure are not limited thereto. Accordingly, red light, green light, and blue light emitted from the plurality of light-emitting elements ED may be combined to implement light of various colors including white. The types of the plurality of light-emitting elements ED are exemplary, and the implementations of the present disclosure are not limited thereto.

A second connection electrode CE2 may be disposed in each of the plurality of light-emitting elements. The second connection electrode CE2 may be disposed on the light-emitting element ED. The second connection electrode CE2 may be electrically connected to the pixel driving circuit PD through a plurality of contact electrodes CCE.

For example, the second connection electrode CE2 may be electrically connected to the second electrode 135 of the light-emitting element ED to transmit a cathode voltage output from the pixel driving circuit PD to the light-emitting element ED. The same cathode voltage may be applied to the second connection electrode CE2 of each of the plurality of light-emitting elements. For example, the same voltage may be applied to the second connection electrode CE2 of each of the plurality of light-emitting elements and the second electrode 135 of the light-emitting element ED. Accordingly, the second connection electrode CE2 may be a common electrode, but the implementations of the present disclosure are not limited thereto.

At least some of the plurality of light-emitting elements may share the second connection electrode CE2. At least some of the second electrodes CE2 of the plurality of light-emitting elements may be electrically connected. Since the same voltage is applied to the second connection electrodes CE2, the second connection electrodes CE2 of at least some light-emitting elements may be shared and used. For example, the second connection electrodes CE2 of at least some of the plurality of light-emitting elements disposed in the same row may be connected. For example, one second connection electrode CE2 may be disposed in the plurality of light-emitting elements. One second connection electrode CE2 may be disposed in each of N light-emitting elements.

For example, some of the second connection electrodes CE2 of the plurality of light-emitting elements may be disposed to be spaced apart from each other or disposed separately. For example, a second connection electrode CE2 connected to light-emitting elements in an nth row and a second connection electrode CE2 connected to light-emitting elements in an (n+1)th row may be disposed to be spaced apart from each other or disposed separately. For example, the plurality of second connection electrodes CE2 may be disposed to be spaced apart from each other with the plurality of communication lines TL extending in a row direction interposed therebetween. Accordingly, the number of plurality of light-emitting elements may be more than the number of plurality of second connection electrodes CE2. As another example, all of the second connection electrodes CE2 of the plurality of light-emitting elements may be connected so that only one second connection electrode CE2 may be disposed on the substrate 110, and the implementations of the present disclosure are not limited thereto.

The plurality of second connection electrodes CE2 may be formed of a transparent conductive material, but the implementations of the present disclosure are not limited thereto. The plurality of second connection electrodes CE2 may be formed of a transparent conductive material so that light emitted from the light-emitting element ED may travel upward with respect to the second connection electrodes CE2. For example, the second connection electrode CE2 may be formed of a transparent conductive material, such as indium tin oxide (ITO), indium zinc oxide (IZO), indium gallium zinc oxide (IGZO), etc., but the implementations of the present disclosure are not limited thereto.

The second connection electrode CE2 may have a fourth uneven pattern that corresponds to the third uneven pattern of the second electrode 135 and is formed at a portion in contact with the second electrode 135.

A black matrix BM may be disposed on the second connection electrode CE2, the first optical layer 117a, and the second optical layer 117b. For example, the black matrix BM may fill a contact hole of the second optical layer 117b. Since the black matrix BM is formed to cover the active area AA, it is possible to reduce color mixing of light and external light reflection of a plurality of light-emitting elements. For example, since the black matrix BM is also disposed in a contact hole by which the second connection electrode CE2 and the contact electrode CCE are connected, it is possible to prevent or at least reduce light leakage between neighboring light-emitting elements.

For example, the black matrix B M may be formed of an opaque material, but the implementations of the present disclosure are not limited thereto. For example, the black matrix BM may be an organic insulation material to which a black pigment or black dye is added, but the implementations of the present disclosure are not limited thereto.

Referring to FIG. 2, the display device 100 according to the embodiment of the present disclosure may have the plurality of contact electrodes CCE disposed on the substrate 110. For example, the plurality of contact electrodes CCE may be disposed to be spaced apart from the plurality of bank layers BNK and the plurality of signal lines TL. Each of the plurality of second connection electrodes CE2 may overlap at least one contact electrode CCE. For example, one second connection electrode CE2 may overlap the plurality of contact electrodes CCE.

For example, the plurality of contact electrodes CCE may be electrically connected to the plurality of second connection electrodes CE2. The plurality of contact electrodes CCE may be disposed between the substrate 110 and the plurality of second connection electrodes CE2 to transmit the cathode voltage output from the pixel driving circuit PD to the second connection electrode CE2.

For example, when a micro LED is used as the light-emitting element ED, the display device 100 may be manufacturing by forming a plurality of micro LED on a wafer and transferring the micro LED onto the substrate 110 of the display device 100. During the process of transferring the plurality of light-emitting elements ED having a micro size from the wafer onto the substrate 110, various types of defects may occur. For example, a non-transfer defect in which the light-emitting element ED is not transferred may occur in some sub-pixels, and a defect in which the light-emitting element ED is transferred out of a correct location due to an alignment error may occur in other sub-pixels. In addition, the transfer process may be normally performed, but the transferred light-emitting element ED may be defective. Accordingly, in consideration of defects during the transfer process of the plurality of light-emitting elements ED, the plurality of light-emitting elements ED of the same type may be transferred onto one sub-pixel. A turn-on test of the plurality of light-emitting elements ED may be performed, and only one light-emitting element ED that is ultimately determined to be normal may be used.

For example, both a 1-1 light-emitting element 130 and a 1-2 light-emitting element 130 may be transferred onto one pixel, and whether the 1-1 light-emitting element 130 and the 1-2 light-emitting element 130 are defective may be tested. When it is determined that both the 1-1 light-emitting element 130 and the 1-2 light-emitting element 130 are normal, only the 1-1 light-emitting element 130 may be used, and the 1-2 light-emitting element 130 may not be used. As another example, when it is determined that only the 1-2 light-emitting element 130 among the 1-1 light-emitting element 130 and the 1-2 light-emitting element 130 are normal, the 1-1 light-emitting element 130 is not used, and only the 1-2 light-emitting element 130 may be used. Accordingly, even when the plurality of light-emitting elements ED of the same type are transferred onto one pixel, only one light-emitting element ED may be ultimately used.

Accordingly, one of the pair of light-emitting elements ED may be a main (or primary) light-emitting element ED, and the other may be a redundancy light-emitting element ED. The redundancy light-emitting element ED may be a spare light-emitting element ED transferred in preparation of a defect of the main light-emitting element ED. When the main light-emitting element ED is defective, the defective main light-emitting element ED may be replaced with the redundancy light-emitting element ED and used. Accordingly, by transferring both the main light-emitting element ED and the redundancy light-emitting element ED onto one pixel, it is possible to minimize the degradation of display quality due to defects of the main light-emitting element ED and the redundancy light-emitting element ED.

For example, the 1-1 light-emitting element 130, the 2-1 light-emitting element 140, and the 3-1 light-emitting element 150 that are transferred onto one pixel may be used as the main light-emitting element ED, and the 1-2 light-emitting element 130, the 2-2 light-emitting element 140, and the 3-2 light-emitting element 150 may be used as the redundancy light-emitting element ED.

Referring to FIG. 2, the display device 100 according to the embodiment of the present disclosure may have a first buffer layer 111a and a second buffer layer 111b that are disposed in the remaining area of the substrate 110 not including the bending area BA.

The first buffer layer 111a and the second buffer layer 111b may be disposed in the active area AA, the first non-active area NA1, and the second non-active area NA2. The first buffer layer 111a and the second buffer layer 111b can reduce the penetration of moisture or impurities into the substrate 110. The first buffer layer 111a and the second buffer layer 111b may be formed of an inorganic insulation material. For example, the first buffer layer 111a and the second buffer layer 111b may be formed of a single layer or multiple layers of silicon oxide (SiOx) or silicon nitride (SiNx), but the implementations of the present disclosure are not limited thereto.

For example, parts of the first buffer layer 111a and the second buffer layer 111b on the bending area BA may be removed. An upper surface of the substrate 110 located in the bending area BA may be exposed from the first buffer layer 111a and the second buffer layer 111b. By removing the first buffer layer 111a and the second buffer layer 111b, which are formed of an inorganic insulation material, from the bending area BA, it is possible to minimize cracks in the first buffer layer 111a and the second buffer layer 111b, which may occur during bending.

A plurality of alignment keys M K may be disposed between the first buffer layer 111a and the second buffer layer 111b. The plurality of alignment keys M K may be formed to identify the location of the pixel driving circuit PD during the manufacturing process of the display device 100. For example, the plurality of alignment keys MK may be formed to align the location of the pixel driving circuit PD transferred onto an adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. As another example, at least a part of the adhesive layer 112 may be removed from the non-active area NA including the bending area BA. For example, the adhesive layer 112 may be formed of one of an adhesive polymer, an epoxy resin, a UV-curable resin, a polyimide-based material, an acrylate-based material, a urethane-based material, and a polydimethylsiloxane (PDMS), but the implementations of the present disclosure are not limited thereto.

The pixel driving circuit PD may be disposed on the adhesive layer 112 in the active area AA. The pixel driving unit PD may be disposed in the form of a chip. Accordingly, the pixel driving circuit PD may be referred to as a “driving chip.” When the pixel driving circuit PD is implemented as a driving driver, the driving driver may be mounted on the adhesive layer 112 by a transfer process, but the implementations of the present disclosure are not limited thereto.

The driving chip PD may be disposed under the plurality of light-emitting elements 130, 140, and 150. The driving chip PD may be electrically connected to each of the plurality of light-emitting elements 130, 140, and 150.

A first protective layer 113a and a second protective layer 113b may be disposed on the adhesive layer 112 and the pixel driving circuit PD. The first protective layer 113a and the second protective layer 113b may be disposed to surround side surfaces of the pixel driving circuit PD, but the implementations of the present disclosure are not limited thereto. For example, the second protective layer 113b may be disposed to cover at least a part of the upper surface of the pixel driving circuit PD. For example, at least one of the first protective layer 113a and the second protective layer 113b that are disposed on the bending area BA may be omitted. For example, the first protective layer 113a may be entirely disposed in the active area AA and the non-active area NA, and a part of the second protective layer 113b may be disposed in the active area AA, the first non-active area NA1, and the second non-active area NA2. For example, a part of the second protective layer 113b in the bending area BA may be removed. However, the implementations of the present disclosure are not limited thereto.

The first protective layer 113a and the second protective layer 113b may be formed of an organic insulation material, but the implementations of the present disclosure are not limited thereto. For example, the first protective layer 113a and the second protective layer 113b may be formed of a photoresist, polyimide (PI), or photo acryl-based material, but the implementations of the present disclosure are not limited thereto. For example, the first protective layer 113a and the second protective layer 113b may be an overcoating layer or an insulating layer, but the implementations of the present disclosure are not limited thereto.

According to the present disclosure, a plurality of first connection lines 121 may be disposed on the second protective layer 113b in the active area AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the implementations of the present disclosure are not limited thereto.

For example, the plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit the voltage output from the pixel driving circuit PD to the first connection electrode CE1 or the second connection electrode CE2.

For example, the third protective layer 114 may be disposed on the second protective layer 113b. The third protective layer 114 may be disposed across the active area AA and the non-active area NA. In the bending area BA, the third protective layer 114 may cover side surfaces of the second protective layer 113b and an upper surface of the first protective layer 113a. The third protective layer 114 may be formed of an organic insulation material. For example, the third protective layer 114 may be formed of a photoresist, polyimide (PI), or photo acryl-based material, but the implementations of the present disclosure are not limited thereto. For example, the first protective layer 113a, the second protective layer 113b, and the third protective layer 114 may be formed of the same material. The implementations of the present disclosure are not limited thereto.

The plurality of 1-2 connection lines 121b may be disposed on the third protective layer 114. The plurality of 1-2 connection lines 121b may be connected or directly connected to the pixel driving circuit PD. For example, a part of the 1-2 connection line 121b may be directly connected to the pixel driving circuit PD through a contact hole of the third protective layer 114. The other part of the 1-2 connection line 121b may be electrically connected to the 1-1 connection line 121a through a contact hole of the third protective layer 114. However, the implementations of the present disclosure are not limited thereto. The voltage output from the pixel driving circuit PD may be transmitted to the first connection electrode CE1 or the second connection electrode CE2 through the plurality of 1-2 connection lines 121b and other connection lines.

A first insulating layer 115a may be disposed on the plurality of 1-2 connection lines 121b. The first insulating layer 115a may be disposed across the active area AA and the non-active area NA, but the implementations of the present disclosure are not limited thereto. The first insulating layer 115a may be formed of an organic insulation material, but the implementations of the present disclosure are not limited thereto. For example, the first insulating layer 115a may be formed of a photoresist, polyimide (PI), or photo acryl-based material, but the implementations of the present disclosure are not limited thereto.

The plurality of 1-3 connection lines 121c may be disposed on the first insulating layer 115a. The plurality of 1-3 connection lines 121c may be electrically connected to the plurality of 1-2 connection lines 121b. For example, the 1-3 connection line 121c may be electrically connected to the 1-2 connection line 121b through a contact hole of the first insulating layer 115a.

A second insulating layer 115b may be disposed on the plurality of the 1-3 connection lines 121c. The second insulating layer 115b may be disposed in the remaining area not including the bending area BA, but the implementations of the present disclosure are not limited thereto. The second insulating layer 115b may be disposed in the active area AA, the first non-active area NA1, and the second non-active area NA2, but the implementations of the present disclosure are not limited thereto. For example, a part of the second insulating layer 115b disposed in the bending area BA may be removed. The second insulating layer 115b may be formed of an organic insulation material, but the implementations of the present disclosure are not limited thereto. For example, the second insulating layer 115b may be formed of a photoresist, polyimide (PI), or photo acryl-based material, but the implementations of the present disclosure are not limited thereto.

A plurality of 1-4 connection lines 121d may be disposed on the second insulating layer 115b. The plurality of 1-4 connection lines 121d may be electrically connected to the plurality of 1-3 connection lines 121c. For example, the plurality of 1-4 connection lines 121d may be electrically connected to the 1-3 connection line 121c through contact holes of the second insulating layer 115b.

According to the present disclosure, a plurality of second connection lines 122 may be disposed on the second protective layer 113b in the non-active area NA. The plurality of second connection lines 122 may be lines for transmitting signals transmitted from the flexible circuit board (or the flexible film) 157 and the printed circuit board 160 (see FIG. 1) to the pad part PAD to the pixel driving circuit PD of the active area AA. For example, the plurality of second connection lines 122 may be electrically connected to the plurality of pad electrodes PE to receive signals from the flexible circuit board (or the flexible film) 157 and the printed circuit board.

For example, the plurality of second connection lines 122 may extend from the pad part PAD toward the active area AA to transmit signals to lines of the active area AA. In this case, the plurality of second connection lines 122 may serve as the link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may extend from the second non-active area NA2 to the bending area BA and the first non-active area NA1. The plurality of 2-1 connection lines 122a may transmit the signals transmitted from the flexible circuit board (or the flexible film) 157 and the printed circuit board to the pad part PAD to the pixel driving circuit PD of the active area AA.

The plurality of 2-2 connection lines 122b may be disposed on the third protective layer 114. The plurality of 2-2 connection lines 122b may be disposed in the second non-active area NA2. The 2-2 connection line 122b may be electrically connected to the 2-1 connection line 122a through a contact hole of the third protective layer 114. Accordingly, the signals output from the flexible circuit board (or the flexible film) 157 and the printed circuit board may be transmitted to the 2-1 connection line 122a through the 2-2 connection line 122b.

The 2-3 connection line 122c may be disposed on the first insulating layer 115a. The 2-3 connection line 122c may be disposed in the second non-active area NA2. The 2-3 connection line 122c may be electrically connected to the 2-2 connection line 122b through a contact hole of the first insulating layer 115a. Accordingly, the signals output from the flexible circuit board (or the flexible film) 157 and the printed circuit board may be transmitted to the 2-1 connection line 122a through the 2-3 connection line 122c and the 2-2 connection line 122b.

The 2-4 connection line 122d may be disposed on the second insulating layer 115b. The 2-4 connection line 122d may be disposed in the second non-active area NA2. The 2-4 connection line 122d may be electrically connected to the 2-3 connection line 122c through a contact hole of the second insulating layer 115b. Accordingly, the signals output from the flexible film FF and the printed circuit board may be transmitted to the 2-1 connection line 122a through the 2-4 connection line 122d, the 2-3 connection line 122c, and the 2-2 connection line 122b.

The plurality of first connection lines 121 and the plurality of second connection lines 122 may be formed of an excellent flexible conductive material or one of various conductive materials used in the active area AA. For example, the second connection line 122 of which a part is disposed in the bending area BA may be formed of an excellent flexible conductive material, such as gold (Au), silver (Ag), aluminum (Al), etc., but the implementations of the present disclosure are not limited thereto. As another example, the plurality of first connection lines 121 and the plurality of second connection lines 122 may be formed of molybdenum (Mo), chromium (Cr), titanium (Ti), nickel (Ni), neodymium (Nd), copper (Cu), and an alloy of silver (Ag) and magnesium (Mg), or an alloy thereof, but the implementations of the present disclosure are not limited thereto.

The third insulating layer 115c may be disposed on the plurality of first connection lines 121 and the plurality of second connection lines 122. The third insulating layer 115c may be disposed in the remaining area not including the bending area BA, but the implementations of the present disclosure are not limited thereto. The third insulating layer 115c may be disposed in the active area AA, the first non-active area NA1, and the second non-active area NA2. A part of the third insulating layer 115c in the bending area BA may be removed. The third insulating layer 115c may be formed of an organic insulation material, but the implementations of the present disclosure are not limited thereto. For example, the third insulating layer 115c may be formed of a photoresist, polyimide (PI), or photo acryl-based material, but the implementations of the present disclosure are not limited thereto.

The plurality of bank layers BNK may be disposed on the third insulating layer 115c in the active area AA. The plurality of bank layers BNK may be disposed to overlap the plurality of sub-pixels, respectively. One or more light-emitting elements ED of the same type may be disposed on each of the plurality of bank layers BNK.

The plurality of signal lines TL may be disposed on the third insulating layer 115c in the active area AA. The plurality of signal lines TL may be disposed in an area between the plurality of bank layers BNK. For example, the plurality of signal lines TL may be disposed adjacent to one of the plurality of bank layers BNK.

The plurality of contact electrodes CCE may be disposed on the third insulating layer 115c in the active area AA. The plurality of contact electrodes CCE may supply the cathode voltage output from the pixel driving circuit PD to the second connection electrode CE2.

In each of the plurality of light-emitting elements 130, 140, and 150, the first electrode 131 may be bonded to the first connection electrode CE1 by the eutectic bonding of the first bonding electrode 138 and the second bonding electrode SDP.

For such bonding, the second bonding electrode SDP may be disposed on the first connection electrode CE1, and the first bonding electrode 138 may be disposed on the second bonding electrode SDP. The first connection electrode CE1 may be disposed on the bank layer BNK. For example, the first connection electrode CE1 may be disposed to extend from an adjacent signal line TL upward from the bank layer BNK. The first connection electrode CE1 may be disposed on an upper surface of the bank layer BNK and side surfaces of the bank layer BNK. For example, the first connection electrode CE1 may be disposed to extend from the signal line TL on an upper surface of the third insulating layer 115c to the side surfaces of the bank layer BNK and the upper surface of the bank layer BNK.

Each of the plurality of light-emitting elements 130, 140, and 150 may include a micro LED.

The plurality of light-emitting elements 130, 140, and 150 may include at least one of the first light-emitting element 130 of a red color, the second light-emitting element 140 of a green color, and the third light-emitting element 150 of a blue color.

The first connection electrode CE1 may have a mirror shape in which a part of a surface in contact with the second bonding electrode SDP is removed or etched inward to expose an internal reflective material.

Referring to FIG. 3, the first connection electrode CE1 may include a plurality of conductive layers. For example, the first connection electrode CE1 may include a first conductive layer CE1a, a second conductive layer CE1b, a third conductive layer CE1c, and a fourth conductive layer CE1d, but the implementations of the present disclosure are not limited thereto.

The first conductive layer CE1a may be disposed on the bank layer BNK. The second conductive layer CE1b may be disposed on the first conductive layer CE1a. The third conductive layer CE1c may be disposed on the second conductive layer CE1b, and the fourth conductive layer CE1d may be disposed on the third conductive layer CE1c. For example, each of the first conductive layer CE1a, the second conductive layer CE1b, the third conductive layer CE1c, and the fourth conductive layer CE1d may be formed of titanium (Ti), molybdenum (Mo), aluminum (Al), or titanium (Ti) and indium tin oxide (ITO), but the implementations of the present disclosure are not limited thereto.

According to the present disclosure, some of the plurality of conductive layers constituting the first connection electrode CE1, which have good reflection efficiency, may be formed as an alignment key for aligning the light-emitting element ED and/or a reflector. For example, the second conductive layer CE1b among the plurality of conductive layers of the first connection electrode CE1 may include a reflective material. For example, the second conductive layer CE1b may include aluminum (Al), but the implementations of the present disclosure are not limited thereto. Accordingly, the second conductive layer CE1b may be formed as a reflector. In addition, due to the high reflection efficiency of the second conductive layer CE1b, the second conductive layer CE1b can be easily identified during the manufacturing process, and thus the location or transfer location of the light-emitting element ED may be aligned based on the second conductive layer CE1b.

For example, to form the second conductive layer CE1b as a reflector, parts of the third conductive layer CE1c and the fourth conductive layer CE1d that cover the second conductive layer CE1b may be removed or etched. For example, parts of the third conductive layer CE1c and the fourth conductive layer CE1d that are disposed on the bank layer BNK may be removed or etched to expose an upper surface of the second conductive layer CE1b. For example, central and edge portions of the third conductive layer CE1c and the fourth conductive layer CE1d in which the solder pattern SDP is disposed may remain, and the remaining parts not including the central and edge portions may be removed. For example, the edge portion of each of the third conductive layer CE1c formed of titanium (Ti) and the fourth conductive layer CE1d formed of indium tin oxide (ITO) may not be etched. Accordingly, it is possible to prevent other conductive layers of the first electrode CE1 from being corroded by a tetramethylammonium hydroxide (TMAH) solution used in a mask process of the first connection electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has high adhesion to the solder pattern SDP, corrosion resistance, and acid resistance. However, the implementations of the present disclosure are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the implementations of the present disclosure are not limited thereto.

According to the present disclosure, the signal line TL, the contact electrode CCE, and the pad electrode PE that are disposed on the same layer as the first connection electrode CE1 may be formed in conductive multiple layers, but the implementations of the present disclosure are not limited thereto. For example, the signal line TL, the contact electrode CCE, and the pad electrode PE may be formed in multiple layers of indium tin oxide (ITO)/titanium (Ti)/aluminum (Al)/titanium (Ti), but the implementations of the present disclosure are not limited thereto.

According to the present disclosure, the second bonding electrode SDP may be disposed on the first connection electrode CE1 in each of the plurality of sub-pixels. The second bonding electrode SDP may bond the light-emitting element ED to the first connection electrode CE1. The first connection electrode CE1 and the light-emitting element ED may be electrically connected through eutectic bonding using the second bonding electrode SDP, but the implementations of the present disclosure are not limited thereto. For example, when the second bonding electrode SDP is formed of indium (In) and the first bonding electrode 138 of the light-emitting element ED is formed of gold (Au), the second bonding electrode SDP and the first bonding electrode 138 may be bonded by applying heat and pressure during the transfer process of the light-emitting element ED. The light-emitting element ED may be bonded to the second bonding electrode SDP and the first bonding electrode 138 without a separate adhesive through eutectic bonding. For example, the second bonding electrode SDP may be formed of indium (In), tin (Sn), or an alloy thereof, but the implementations of the present disclosure are not limited thereto. For example, the second bonding electrode SDP may be a bonding pad, etc., but the implementations of the present disclosure are not limited thereto.

According to the present disclosure, a passivation layer 116 may be disposed on the plurality of signal lines TL, the plurality of first connection electrodes CE1, the plurality of contact electrodes CCE, and the third insulating layer 115c. For example, the passivation layer 116 may be disposed in the active area AA, the first non-active area NA1, and the second non-active area NA2. A part of the passivation layer 116 disposed in the bending area BA may be removed. A part of the passivation layer 116 covering the plurality of pad electrodes PE in the second non-active area NA2 may be removed. Since the passivation layer 116 is disposed to cover the remaining area not including the bending area BA, the plurality of pad electrodes PE, and the area in which the second bonding electrode SDP is disposed, it is possible to reduce the penetration of moisture or impurities into the light-emitting element ED. For example, the passivation layer 116 may be formed of a single layer or multiple layers of silicon oxide (SiOx) or silicon nitride (SiNx), but the implementations of the present disclosure are not limited thereto. For example, the passivation layer 116 may be a protective layer, an insulating layer, etc., but the implementations of the present disclosure are not limited thereto. For example, the passivation layer 116 may include a hole exposing the second bonding electrode SDP.

The light-emitting element ED may be disposed on the second bonding electrode SDP in each of the plurality of sub-pixels. The first light-emitting element 130 may be disposed in the first sub-pixel. The second light-emitting element 140 may be disposed in the second sub-pixel. The third light-emitting element 150 may be disposed in the third sub-pixel. The plurality of light-emitting elements 130, 140, and 150 may be micro light-emitting elements.

The light-emitting element ED may be formed on a silicon wafer by a method of metal organic chemical vapor deposition (MOCVD), CVD, plasma-enhanced CVD (PECVD), molecular beam epitaxy (MBE), hydride vapor phase epitaxy (HVPE), sputtering, etc., but the implementations of the present disclosure are not limited thereto.

Referring to FIG. 3, in a light-emitting part EA, the first connection electrode CE1 may be disposed on the bank layer BNK, the second bonding electrode SDP may be disposed on the first connection electrode CE1, and the light-emitting element ED (131, 132, 133, 134, 135, 136, 137, and 138) may be disposed on the second bonding electrode SDP.

In the light-emitting element, the first bonding electrode 138 may be disposed on the second bonding electrode SDP, the first and second passivation layers 136 and 137 may be disposed on the first bonding electrode 138, and the first electrode 131 may be disposed on the second passivation layer 137. The implementations of the present disclosure are not limited thereto.

In this case, the first bonding electrode 138 may be electrically connected to the first electrode 131 through a plurality of through holes after passing through the first passivation layer 136 and the second passivation layer 137.

The bank layer BNK and an encapsulation layer ENC surrounding the first connection electrode CE1 may be disposed on the first connection electrode CE1, but the implementations of the present disclosure are not limited thereto. For example, the encapsulation layer ENC may not be included in the first light-emitting element 130.

One of the first semiconductor layer 132 and the second semiconductor layer 134 may be implemented as, for example, a compound semiconductor of group III-V, group II-VI, etc, and may be doped with an impurity (or a dopant). For example, one of the first semiconductor layer 132 and the second semiconductor layer 134 may be a semiconductor layer doped with an n-type impurity, and the other may be a semiconductor layer doped with a p-type impurity, but the implementations of the present disclosure are not limited thereto. For example, at least one of the first semiconductor layer 132 and the second semiconductor layer 134 may be a layer formed of a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), etc., coated with an n-type or p-type impurity, but the implementations of the present disclosure are not limited thereto. For example, the n-type impurity may be silicon (Si), germanium (Ge), selenium (Se), carbon (C), tellurium (Te), tin (Sn), etc., but the implementations of the present disclosure are not limited thereto. For example, the p-type impurity may be magnesium (Mg), zinc (Zn), calcium (Ca), strontium (Sr), barium (Ba), beryllium (Be), etc., but the implementations of the present disclosure are not limited thereto.

For example, the first semiconductor layer 132 and the second semiconductor layer 134 may be a nitride semiconductor including an n-type impurity and a nitride semiconductor including a p-type impurity, respectively, but the implementations of the present disclosure are not limited thereto. For example, the first semiconductor layer 132 may be a nitride semiconductor including a p-type impurity, and the second semiconductor layer 134 may be a nitride semiconductor including an n-type impurity, but the implementations of the present disclosure are not limited thereto.

The active layer 133 may be disposed between the first semiconductor layer 132 and the second semiconductor layer 134. The active layer 133 may receive holes and electrons from the first semiconductor layer 132 and the second semiconductor layer 134 and emit light. For example, the active layer 133 may be formed in one of a single well structure, a multi-well structure, a single quantum well structure, a MQW structure, a quantum dot structure, and a quantum wire structure, but the implementations of the present disclosure are not limited thereto. For example, the active layer 133 may be formed of indium gallium nitride (InGaN), gallium nitride (GaN), etc., but the implementations of the present disclosure are not limited thereto.

As another example, the active layer 133 may include an MQW structure that has a well layer and a barrier layer having a greater band gap than the well layer. For example, the active layer 133 may have an InGaN layer as the well layer and an AlGaN layer as the barrier layer, but the implementations of the present disclosure are not limited thereto.

The first electrode 131 may be disposed between the first semiconductor layer 132 and the second bonding electrode SDP. For example, the first electrode 131 may electrically connect the first semiconductor layer 132 to the first connection electrode CE1. The anode voltage output from the pixel driving circuit PD may be applied to the first semiconductor layer 132 through the signal line TL, the first connection electrode CE1, and the first electrode 131. For example, the first electrode 131 may be formed of a conductive material capable of eutectic bonding with the second bonding electrode SDP, but the implementations of the present disclosure are not limited thereto. For example, the first electrode 131 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), an alloy thereof, etc., but the implementations of the present disclosure are not limited thereto. For example, the first electrode 131 be formed of a material, such as indium tin oxide (ITO), indium zinc oxide (IZO), indium gallium zinc oxide (IGZO), etc., but the implementations of the present disclosure are not limited thereto.

Each of the second semiconductor layer 134 and the second electrode 135 may have an uneven pattern formed at a portion in contact with each other, and the uneven patterns may come into contact with each other in a coupled form.

The second electrode 135 may be disposed on the second semiconductor layer 134. For example, the second electrode 135 may electrically connect the second semiconductor layer 134 to the second connection electrode CE2. The cathode voltage output from the pixel driving circuit PD may be applied to the second semiconductor layer 134 through the contact electrode CCE, the second connection electrode CE2, and the second electrode 135. The second electrode 135 may be formed of a transparent conductive material so that light emitted from the light-emitting element ED may travel upward with respect to the light-emitting element ED, but the implementations of the present disclosure are not limited thereto. For example, the second electrode 135 be formed of a material, such as indium tin oxide (ITO), indium zinc oxide (IZO), indium gallium zinc oxide (IGZO), etc., but the implementations of the present disclosure are not limited thereto.

The first passivation layer 136 may be disposed on at least parts of the first electrode 131, the first semiconductor layer 132, the active layer 133, the second semiconductor layer 134, and the second electrode 135. For example, the first passivation layer 136 may surround at least parts of the first electrode 131, the first semiconductor layer 132, the active layer 133, the second semiconductor layer 134, and the second electrode 135.

For example, the first passivation layer 136 may protect the first semiconductor layer 132, the active layer 133, and the second semiconductor layer 134. For example, the first passivation layer 136 may be disposed on side surfaces of the first semiconductor layer 132, side surfaces of the active layer 132, and side surfaces of the second semiconductor layer 134.

For example, the first passivation layer 136 may be disposed on at least parts of the first electrode 131 and the second electrode 135, for example, an edge portion (or one side) of the first electrode 131 and an edge portion (or one side) of the second electrode 135. The at least a part of the first electrode 131 may be exposed with respect to the first passivation layer 136 so that the first electrode 131 and the second bonding electrode SDP may be connected. For example, at least a part of the second electrode 135 may be exposed with respect to the first passivation layer 136 so that the second electrode 135 and the second connection electrode CE2 may be connected. For example, the first passivation layer 136 may be formed of an insulation material, such as silicon nitride (SiNx) or silicon oxide (SiOx), but the implementations of the present disclosure are not limited thereto.

As another example, the first passivation layer 136 may have a structure in which a reflective material is dispersed in a resin layer, but the implementations of the present disclosure are not limited thereto. For example, the first passivation layer 136 may be manufactured to be a reflector having various structures, but the implementations of the present disclosure are not limited thereto. Light emitted from the active layer 133 may be reflected upward by the first passivation layer 136, thereby increasing light extraction efficiency. For example, the first passivation layer 136 may be a reflective layer, but the implementations of the present disclosure are not limited thereto.

The encapsulation layer ENC may be disposed on at least parts of the bank layer BNK, the first connection electrode CE1, and the second bonding electrode SDP. For example, the encapsulation layer ENC may surround at least parts of the bank layer BNK, the first connection electrode CE1, and the second bonding electrode SDP.

According to the present disclosure, the light-emitting element ED has been described as having a vertical structure, but the implementations of the present disclosure are not limited thereto. For example, the light-emitting element ED may have a lateral structure or a flip chip structure.

The first light-emitting element 130 has been described with reference to FIG. 3, but the second light-emitting element 140 and the third light-emitting element 150 may have substantially the same structure as the first light-emitting element 130. For example, the second light-emitting element 140 and the third light-emitting element 150 may be substantially the same as the first electrode 131, the first semiconductor layer 132, the active layer 133, the second semiconductor layer 134, the second electrode 135, the first and second passivation layers 136 and 137, and the first bonding electrode 138 of the first light-emitting element 130.

Referring to FIG. 2, the optical insulating layer 117 may include the first optical layer 117a, the second optical layer 117b, and the third optical layer 117c.

According to the present disclosure, the first optical layer 117a surrounding the plurality of light-emitting elements ED may be disposed in the active area AA. For example, the first optical layer 117a may be disposed to cover the plurality of light-emitting elements ED and bank layers BNK in the area of the plurality of sub-pixels. For example, the first optical layer 117a may cover the bank layer BNK, a part of the passivation layer 116, and a space between the plurality of light-emitting elements ED. The first optical layer 117a may be disposed between the plurality of light-emitting elements ED and between the plurality of bank layers BNK that are included in one pixel. For example, the first optical layers 117a may be disposed to extend in a first direction X and spaced apart from each other in a second direction Y. For example, the first optical layer 117a may be disposed to surround the side portions of the light-emitting element ED and the bank layer BNK between the passivation layer 116 and the second connection electrode CE2, but the implementations of the present disclosure are not limited thereto. For example, the first optical layer 117a may be a diffusion layer, a sidewall diffusion layer, etc., but the implementations of the present disclosure are not limited thereto.

The first optical layer 117a may include an organic insulation material having fine particles dispersed therein, but the implementations of the present disclosure are not limited thereto. For example, the first optical layer 117a may be formed of siloxane having fine metal particles, such as titanium dioxide (TiO2) particles, dispersed therein, but the implementations of the present disclosure are not limited thereto. Light from the plurality of light-emitting elements ED may be scattered by the fine particles dispersed in the first optical layer 117a and emitted to the outside of the display device 100. Accordingly, the first optical layer 117a can increase the extraction efficiency of the light emitted from the plurality of light-emitting elements ED.

For example, the first optical layer 117a may be disposed in each of the plurality of pixels or disposed together in some pixels disposed in the same row, but the implementations of the present disclosure are not limited thereto. For example, the first optical layer 117a may be disposed in each of the plurality of pixels, or the plurality of pixels may share one first optical layer 117a. As another example, each of the plurality of sub-pixels may separately include the first optical layer 117a, but the implementations of the present disclosure are not limited thereto.

According to the present disclosure, the second optical layer 117b may be disposed on the passivation layer 116 in the active area AA. For example, the second optical layer 117b may be disposed to surround the first optical layer 117a.

The second optical layer 117b may be formed of an organic insulation material, but the implementations of the present disclosure are not limited thereto. The second optical layer 117b may be formed of the same material as the first optical layer 117a, but the implementations of the present disclosure are not limited thereto. For example, the first optical layer 117a may include fine particles, and the second optical layer 117b may not include fine particles. For example, the second optical layer 117b may be formed of siloxane, but the implementations of the present disclosure are not limited thereto.

For example, a thickness of the first optical layer 117a may be smaller than a thickness of the second optical layer 117b, but the implementations of the present disclosure are not limited thereto. Accordingly, in a plan view, an area in which the first optical layer 117a is disposed may include a concave portion that is recessed inward more than an upper surface of the second optical layer 117b.

According to the present disclosure, the second connection electrode CE2 may be disposed on the first optical layer 117a and the second optical layer 117b. For example, the second connection electrode CE2 may be electrically connected to the plurality of contact electrodes CCE through contact holes of the second optical layer 117b. For example, the second connection electrode CE2 may be disposed on the plurality of light-emitting elements ED. For example, the second connection electrode CE2 may include a transparent conductive oxide, such as indium tin oxide (ITO), indium zinc oxide (IZO), etc., but the implementations of the present disclosure are not limited thereto. For example, the second connection electrode CE2 may be disposed in contact with the second electrode 135. For example, the second connection electrode CE2 may overlap the first optical layer 117a. For example, the second connection electrode CE2 may cover an outer flat surface of the first optical layer 117a.

The second connection electrode CE2 may extend continuously in the first direction of the substrate 110. Accordingly, the second connection electrode CE2 may be connected in common to the plurality of pixels disposed in the first direction of the substrate 110. For example, the second connection electrode CE2 may be connected in common to the plurality of pixels.

According to the present disclosure, the second connection electrode CE2 may continuously extend on the first optical layer 117a, the second optical layer 117b, and the light-emitting element ED. The area in which the first optical layer 117a is disposed may include the concave portion that is recessed inward more than the upper surface of the second optical layer 117b. Accordingly, a first portion of the second connection electrode CE2 disposed on the first optical layer 117a is disposed along the concave portion, and thus may be disposed at a lower location than a second portion of the second connection electrode CE2 disposed on the second optical layer 117b.

The third optical layer 117c may be disposed on the second connection electrode CE2. The third optical layer 117c may be disposed to overlap the plurality of light-emitting elements ED and the first optical layer 117a. Since the third optical layer 117c is disposed above the second connection electrode CE2 and the plurality of light-emitting elements ED, it is possible to eliminate spots (mura) that may occur in some of the plurality of light-emitting elements ED. For example, when the plurality of light-emitting elements ED are transferred onto the substrate 110 of the display device 100, an area in which distances between the plurality of light-emitting elements ED are not uniform may occur due to a process deviation, etc. When the distances between the plurality of light-emitting elements ED are not uniform, a light-emitting area of each of the plurality of light-emitting elements ED may be disposed non-uniformly, thereby making spots (mura) visible to a user. Accordingly, since the third optical layer 117c formed to uniformly diffuse light is formed above the plurality of light-emitting elements ED, it is possible to reduce the light emitted from some light-emitting elements ED from being visible as a spot. Accordingly, since the light emitted from the plurality of light-emitting elements ED is uniformly diffused by the third optical layer 117c and extracted to the outside of the display device 100, it is possible to improve the luminance uniformity of the display device 100.

The third optical layer 117c may include an organic insulation material having fine particles dispersed therein, but the implementations of the present disclosure are not limited thereto. For example, the third optical layer 117c may be formed of siloxane having fine metal particles, such as titanium dioxide (TiO₂) particles, dispersed therein, but the implementations of the present disclosure are not limited thereto. For example, the third optical layer 117c may be formed of the same material as the first optical layer 117a, but the implementations of the present disclosure are not limited thereto. For example, the third optical layer 117c may be a diffusion layer, a sidewall diffusion layer, etc., but the implementations of the present disclosure are not limited thereto.

According to the present disclosure, the light from the plurality of light-emitting elements ED may be scattered by the fine particles dispersed in the third optical layer 117c and emitted to the outside of the display device 100. The third optical layer 117c may uniformly mix the light emitted from the plurality of light-emitting elements ED, thereby further improving the luminance uniformity of the display device 100. In addition, it is possible to increase the light extraction efficiency of the display device 100 by the light scattered from the fine particles, thereby enabling the low-power driving of the display device 100.

The black matrix BM may be disposed on the second connection electrode CE2, the first optical layer 117a, the second optical layer 117b, and the third optical layer 117c in the active area AA.

A cover layer 118 may be disposed on the black matrix BM in the active area AA. The cover layer 118 may protect components under the cover layer 118. For example, the cover layer 118 may be formed of an organic insulation material, but the implementations of the present disclosure are not limited thereto. For example, the cover layer 118 may be formed of a photoresist, polyimide (PI), or photo acryl-based material, but the implementations of the present disclosure are not limited thereto. For example, the cover layer 118 may be an overcoating layer, an insulating layer, etc., but the implementations of the present disclosure are not limited thereto.

The polarizing layer 293 may be disposed on the cover layer 118 via a first adhesive layer 291. The cover member 155 may be disposed on the polarizing layer 293 via a second adhesive layer 295. For example, the first adhesive layer 291 and the second adhesive layer 295 may include an OCA, an OCR, a PSA, etc., but the implementations of the present disclosure are not limited thereto.

According to the present disclosure, the plurality of pad electrodes PE may be disposed on the third insulating layer 115c in the second non-active area NA2. For example, at least parts of the plurality of pad electrodes PE may be exposed with respect to the passivation layer 116. For example, the plurality of pad electrodes PE may be electrically connected to the 2-4 connection line 122d through a contact hole of the third insulating layer 115c.

An adhesive layer ACF may be disposed on the plurality of pad electrodes PE. The adhesive layer ACF may be an adhesive layer in which conductive balls are dispersed in an insulation material, but the implementations of the present disclosure are not limited thereto. When heat or pressure is applied to the adhesive layer ACF, the conductive balls may be electrically connected at a portion in which the heat or pressure is applied, thereby providing conductive characteristics. The adhesive layer ACF may be disposed between the plurality of pad electrodes PE and the flexible circuit board (or the flexible film) 157 to attach or bond the flexible circuit board (or the flexible film) 157 to the plurality of pad electrodes PE. For example, the adhesive layer ACF may be an anisotropic conductive film (ACF), but the implementations of the present disclosure are not limited thereto.

The flexible circuit board (or the flexible film) 157 may be disposed on the adhesive layer ACF. The flexible circuit board (or the flexible film) 157 may be electrically connected to the plurality of pad electrodes PE through the adhesive layer ACF. Accordingly, signals output from the flexible circuit board (or the flexible film) 157 and the printed circuit board may be transmitted to the pixel driving circuit PD of the active area AA through the plurality of pad electrodes PE, the 2-4 connection line 122d, the 2-3 connection line 122c, the 2-2 connection line 122b, and the 2-1 connection line 122a.

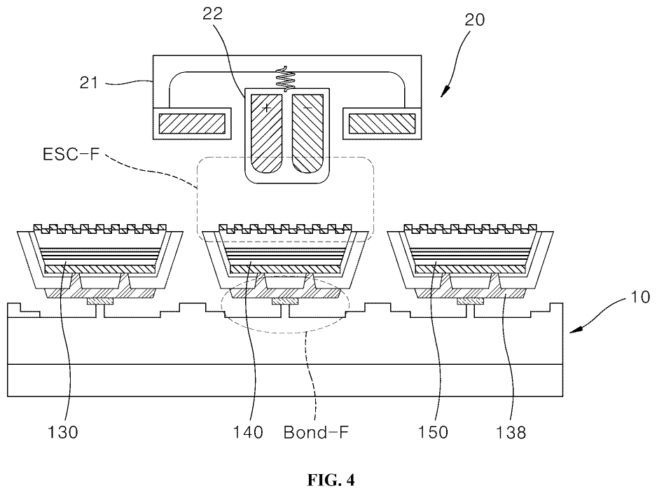

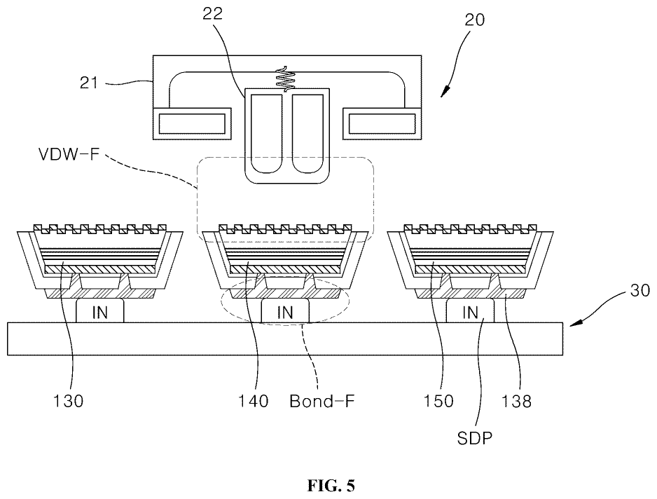

FIG. 4 is a view illustrating an example in which the light-emitting element according to an embodiment of the present disclosure is picked up from a donor member by a transfer member. FIG. 5 is a view illustrating an example in which the light-emitting element according to an embodiment of the present disclosure is placed on the display panel by the transfer member.

Referring to FIGS. 4 and 5, the light-emitting elements 130, 140, and 150 according to the embodiment of the present disclosure may be picked up from a donor element 10 by a transfer member 20 and placed on a display panel 30.

A transport member (not illustrated) may be used to transport the transfer member 20. Meanwhile, although not illustrated in the drawings, the transport member may include a transport head, a head chuck, and a laser transmissive portion. The head chuck may detachably attach the transfer member 20. The laser transmissive portion may transmit a laser and heat and press the light-emitting element 130 during a bonding process of the light-emitting element 130.

The transfer member 20 may pick up the plurality of light-emitting elements 130, 140, and 150 from the donor member 10 and transfer the plurality of light-emitting elements 130, 140, and 150 onto the display panel 30. The transfer member 20 may be formed of a material that transmits a laser.

One light-emitting element 130 may have a chip shape that includes an organic material or an inorganic material. Accordingly, the light-emitting element 130 may be referred to as an “LED chip,” a “light-emitting chip,” or an “element chip.”

The first bonding electrode 138 may be disposed on one surface of the light-emitting element 130. The first bonding electrode 138 may be a bonding product of pressing, melting, and bonding using a laser. Here, the pressing, melting, and bonding refers to a state in which the first bonding electrode 138 is heated and melted by the laser irradiation, mixed with the light-emitting element 130, an anode pad electrode (not illustrated), and a cathode pad electrode (not illustrated), which are melted, and then cooled and solidified when the laser supply is finished. Since conductivity by the light-emitting element 130, the anode pad electrode, and the cathode pad electrode is maintained even while the first bonding electrode 138 is cooled and solidified in a melted and mixed state, the anode pad electrode, the cathode pad electrode, and the light-emitting element 130 may be electrically and physically connected. Accordingly, the first bonding electrode 138 may be disposed on one surface of the light-emitting element 130.

The first bonding electrode 138 may include, for example, gold (Au), a gold and tin compound (AuSn), a palladium and indium compound (PdIn), an indium and tin compound (InSn), a tin and nickel compound (NiSn), a gold compound (Au—Au), an indium and silver compound (AgIn), a silver and tin compound (AgSn), aluminum (Al), silver (Ag), carbon nanotubes (CNT), etc. These may be used alone or in combination of two or more. According to the type of the first bonding electrode 138, the first bonding electrode 138 may be formed by being deposited on the pad electrode or formed on the pad electrode through various methods, such as screen printing, etc.

In addition, each of the light-emitting elements 130 may be transferred onto the anode pad electrode and the cathode pad electrode of the substrate using the transfer member 20. In this case, the substrate may be a sapphire substrate, but the implementations of the present disclosure are not limited thereto.

The light-emitting element 130 may include a micro LED as described above. The micro LED may be formed to a size of about 10 μm to 100 μm. Although not illustrated in the drawings, the micro LED may be manufactured by forming a buffer layer on a substrate and growing a GaN thin film on the buffer layer. In this case, sapphire, silicon (si), GaN, silicon carbide (SIC), gallium arsenide (GaAs), zinc oxide (ZnO), etc. may be used as the substrate for growing a GaN thin film. In the embodiment of the present disclosure, for example, a sapphire substrate may be applied as the substrate for growing a GaN thin film.

In addition, when the substrate for growing a GaN thin film is formed of a material other than a GaN substrate, the buffer layer may be formed of AlN, GaN, etc. to prevent quality from being degraded by lattice mismatch that occurs when growing a n-type GaN layer, which is an epi layer, directly on a substrate.

The n-type GaN layer may be formed by growing an undoped GaN layer and then doping an n-type impurity, such as Si, on an undoped thin film. In addition, ap-type GaN layer may be formed by growing an undoped GaN thin film and then doping a p-type impurity, such as Mg, Zn, or Be.

One or more sub-elements of each of the plurality of light-emitting elements 130, 140, and 150 may be detached from the donor member 10 and transferred onto the display panel 30 through the transfer member 20.

The transfer member 20 may include a base layer 21 and a stamp layer 22 disposed on one surface of the base layer 21.

The pickup method of the transfer member 20 may be diverse. For example, the transfer member 20 may be picked up using chucks of the stamp layer 22. For example, the stamp layer 22 may be picked up by a method of electrostatic chucks, vacuum chucks, physical chucks, etc.

The base layer 21 may be formed of, for example, glass or plastic. When the base layer 21 includes thin glass, the glass may be ultra-thin glass. Alternatively, the base layer 21 may be formed of polyethylene terephthalate (PET), polyurethane (PU), polyimide (PI), polycarbonate (PC), polyethylene (PE), polypropylene (PP), polysulfone (PSF), polymethyl methacrylate (PMMA), triacetyl cellulose (TAC), cycloolefin polymer (COP), etc.

In addition, the transfer member 20 may pick up the plurality of light-emitting elements 130, 140, and 150 in an adhesive manner. In this case, the surface of the stamp layer 22 may be coated with an adhesive or sticky material. The sticky or adhesive material may include, for example, an OCA, a PSA, etc., and the sticky material may include, for example, an acryl-based, urethane-based, or silicon-based adhesive material. Accordingly, the stamp layer 22 may be disposed on one surface of the base layer 21 and stuck or adhered to the plurality of light-emitting elements 130, 140, and 150.

In addition, the embodiment of the present disclosure may further include a heating member although not illustrated in the drawings.

The heating member may provide heat to bond the light-emitting elements 130, 140, and 150. For example, the heating member may provide laser irradiation to the light-emitting elements 130, 140, and 150 through the laser transmissive portion and the transfer member 20. Accordingly, the light-emitting elements 130, 140, and 150 may be pressed, melted, and bonded.

The plurality of light-emitting elements 130, 140, and 150 are disposed on an upper surface of the donor member 10.

To pick up the plurality of light-emitting elements 130, 140, and 150 from the donor member 10, the transfer member 20 may move toward the donor member 10 and correspond to the donor member 10.

The transfer member 20 may be located so that each stamp layer 22 corresponds to each of the plurality of light-emitting elements 130, 140, and 150. The stamp layer 22 may have a spring structure although not illustrated in the drawings. Accordingly, the stamp layer 22 may have an elastic force.

The stamp layer 22 may have an electrostatic force ESC-F with respect to the surface facing the plurality of light-emitting elements 130, 140, and 150. Accordingly, the stamp layer 22 may be adsorbed to the plurality of light-emitting elements 130, 140, and 150 by the electrostatic force ESC-F to pick up the plurality of light-emitting elements 130, 140, and 150.

Although not illustrated, a protective film may be attached to one surface of the stamp layer 22.

The protective film may be formed of, for example, glass or plastic. When the protective film includes thin glass, the glass may be ultra-thin glass.

Before the transfer member 20 picks up the plurality of light-emitting elements 130, 140, and 150 through the stamp layer 22, the protective film attached to the one surface of the stamp layer 22 may be peeled from the stamp layer 22.

In a state in which the transfer member 20 is held by the transport member, the protective film is removed, and the transfer member may pick up the plurality of light-emitting elements 130, 140, and 150 from the donor member 10 using the transfer member 20.

First, the donor member 10 on which the plurality of light-emitting elements 130, 140, and 150 are aligned and disposed is provided. The surface of the donor member 10 may be coated with a sticky material. The donor member 10 and the plurality of light-emitting elements 130, 140, and 150 may be adhered by a sticky material.

The donor member 10 and each of the plurality of light-emitting elements 130, 140, and 150 may be bonded by a bonding force Bond-F through a sticky material.

The transfer member 20 moves to the donor member 10 and adsorbs the plurality of light-emitting elements 130, 140, and 150 to the one surface of the stamp layer 22 using the electrostatic force ESC-F of the stamp layer 22.

Thereafter, the transfer member 20 moves upward (Z-axis direction) to detach the plurality of light-emitting elements 130, 140, and 150 from the donor member 10.

To detach the plurality of light-emitting elements 130, 140, and 150 from the donor member 10 using the transfer member 20, the electrostatic force ESC-F between the stamp layer 22 of the transfer member 20 and the light-emitting elements 130, 140, and 150 needs to be greater than the bonding force Bond-F between the donor member 10 and the light-emitting elements 130, 140, and 150.

The electrostatic force ESC-F between two contact surfaces of the stamp layer 22 and the light-emitting element 130 may be calculated as in the following Equation 1.

$${F}_{ESC} = \frac{{ε}_{0} \cdot A}{2 {d}^{2}} {V}^{2} \qquad [ Equation 1 ]$$

In Equation 1, A denotes a contact area, ε₀ denotes a vacuum permittivity, d denotes a distance between two contact surfaces, and V denotes a voltage.

In addition, the transport member needs to apply a tensile force that is greater than the bonding force Bond-F between the donor member 10 and the light-emitting elements 130, 140, and 150 to the transfer member 20 upward (in the Z-axis direction).

Referring to FIG. 5, the transfer member 20 that has picked up the light-emitting elements 130, 140, and 150 from the donor member 10 moves to the display panel 30 and places the light-emitting elements 130, 140, and 150 on the display panel 30.

Each of the plurality of light-emitting elements 130, 140, and 150 may be detached from the donor member 10 and transferred onto the display panel 30 through the transfer member 20.

The transfer member 20 allows the first bonding electrode 138 of the light-emitting element 130 to correspond to the second bonding electrode SDP on the display panel 30 while picking up the light-emitting element 130 using the van der Waals force VDW-F of the stamp layer 22.

The van der Waals force VDW-F between the two contact surfaces of the stamp layer 22 and the light-emitting element 130 may be calculated as in the following Equation 2.

$${F}_{VDW} = \frac{{A}_{H} \cdot A}{6 π {d}^{3}} \qquad [ Equation 2 ]$$

In Equation 2, A denotes a contact area, A H denotes a Hamaker constant, and d denotes a distance between two contact surfaces.

The transfer member 20 eutectically bonds the first bonding electrode 138 and the second bonding electrode SDP using, for example, laser light.

In each of the light-emitting elements 130, 140, and 150, the first bonding electrode 138 may be eutectically bonded to the second bonding electrode SDP on the display panel 30 and placed and transferred on the display panel 30.

In this case, the second bonding electrode SDP on the display panel 30 may be formed of, for example, indium (In), tin (Sn), or an alloy thereof, but the implementations of the present disclosure are not limited thereto.

For example, when the second bonding electrode SDP is formed of indium (In) and the first bonding electrode 138 of the light-emitting element 130 is formed of gold (Au), the second bonding electrode SDP and the first bonding electrode 138 may be bonded by applying heat and pressure during the transfer process of the light-emitting element 130. The light-emitting element 130 may be bonded to the second bonding electrode SDP and the first bonding electrode 138 without a separate adhesive through eutectic bonding.

When each of the light-emitting elements 130, 140, and 150 is placed and transferred onto the display panel 30, the bonding force Bond-F between the first bonding electrode 138 and the second bonding electrode SDP of the light-emitting element 140 needs to be greater than the van der Waals force VDW-F between the light-emitting element 140 and the stamp layer 22.

Accordingly, the plurality of light-emitting elements 130, 140, and 150 may be placed and transferred onto the display panel 30 by the transfer member 20.

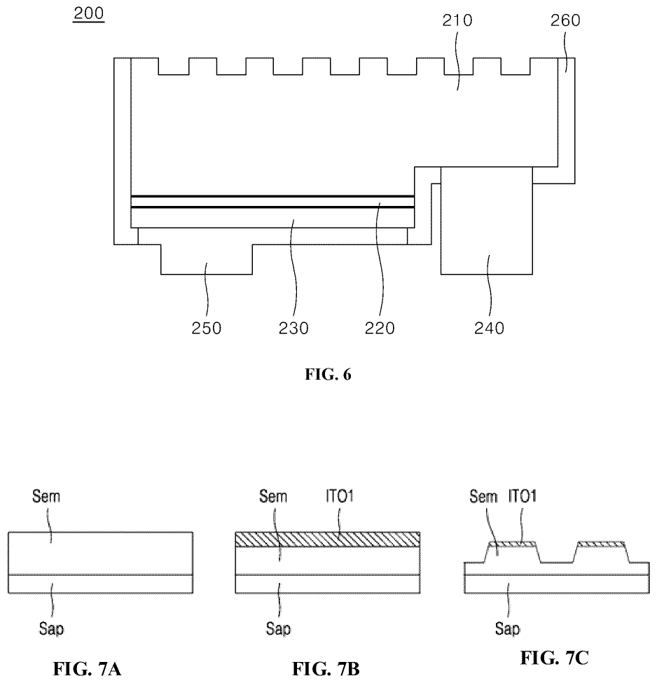

FIG. 6 is a view illustrating an example of a configuration of a light-emitting element according to another embodiment of the present disclosure.

Referring to FIG. 6, a light-emitting element 200 according to another embodiment of the present disclosure may have, for example, a flip chip structure.

The light-emitting element 200 according to another embodiment of the present disclosure may include a second electrode 250, a second semiconductor layer 230 disposed on the second electrode 250, an active layer 220 disposed on the second semiconductor layer 230, a first semiconductor layer 210 disposed on the active layer 220, a first electrode 240 disposed under one side of the first semiconductor layer 210, and a passivation layer 260 surrounding an outer edge of the second electrode, the second semiconductor layer, the active layer, the first semiconductor layer, and the first electrode.

The first semiconductor layer 210 may have an upper portion having an uneven pattern formed by alternating a concave shape and a convex shape.

One of the first semiconductor layer 210 and the second semiconductor layer 230 may be a semiconductor layer doped with an N-type impurity, and the other may be a semiconductor layer doped with a P-type impurity.

The first electrode 240, the second electrode 250, the active layer 220, and the passivation layer 260 may be formed of the same material as the configuration described above in FIG. 1.

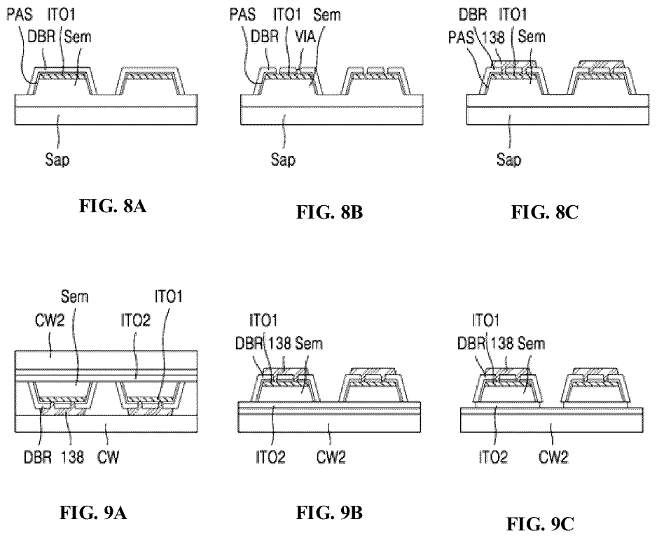

FIGS. 7A to 7C, 8A to 8C, 9A to 9C, and 10A to 10C are views illustrating transfer processes of the light-emitting element according to the embodiment of the present disclosure.

In FIGS. 7A to 7C, 8A to 8C, 9A to 9C, and 10A to 10C, symbols of the same components as the above components are omitted, and the detailed description of a process that is generally known or well-known is also omitted.

In FIG. 7A, in the light-emitting element according to the embodiment of the present disclosure, a semiconductor layer Sem may be formed on a sapphire substrate Sap (operation a).

The semiconductor layer Sem may be formed in a thickness of about 5 to 6 micrometers (μm) through a semiconductor crystal film epitaxial growth (Epi) process.

Subsequently, in FIG. 7B, a first electrode layer ITO1 formed of, for example, an ITO material may be deposited on the semiconductor layer Sem (operation b). The first electrode layer ITO1 may be formed in a thickness of, for example, 120 micrometers (μm).

Subsequently, in FIG. 7C, the semiconductor layer Sem and the first electrode layer ITO1 may be etched through an etching (ISO etch) process (operation c). The semiconductor layer Sem and the electrode layer ITO may be etched to about 3 micrometers (μm) through an ISO (Isolation) process. A thickness of the chip (cip) may be determined by this process.

In FIG. 8A, a passivation layer PAS may be formed on the electrode layer ITO through atomic layer deposition (ALD), and a distributed Bragg reflector DBR may be formed on the passivation layer PAS through a sputtering process (operation d).

The passivation layer PAS and the distributed Bragg reflector DBR may target a wavelength of light, and the thickness for targeting can be minimized or at least reduced.

Subsequently, in FIG. 8B, a plurality of through holes VIA may be formed by opening parts of the passivation layer PAS and the distributed Bragg reflector DBR (operation e). Here, the through hole VIA may have a width of, for example, 1.5 micrometers (μm).

Subsequently, in FIG. 8C, the first bonding electrode 138 may be formed on the passivation layer PAS (operation f).

At this time, the first bonding electrode 138 may come into electrical contact with the electrode layer ITO through the plurality of through holes VIA. The first bonding electrode 138 may be formed of a highly conductive metallic material, for example, a gold (Au) material.

In FIG. 9A, a primary carrier wafer CW may be bonded on the first bonding electrode 138 (operation g).

Subsequently, in FIG. 9B, the sapphire substrate Sap is detached by a laser lift off (LLO) process, and the semiconductor layer Sem is etched by an etching (GaN etch) process (operation h).

Then, in FIG. 9C, a second electrode layer ITO2 may be deposited on the etched semiconductor layer Sem (operation i). The second electrode layer ITO2 may include, for example, indium tin oxide (ITO).

In FIG. 10A, a secondary carrier wafer CW 2 may be bonded on the second electrode layer ITO2 (operation j).

Subsequently, in FIG. 10B, the primary carrier wafer CW may be removed, and a primary adhesive, etc. may also be removed (operation k).

Subsequently, in FIG. 10C, the second electrode layer ITO2 may be separately etched (wet-etched) to remain in each light-emitting element (operation I).

The second electrode layer ITO2 may be the second electrode 135 of FIG. 1, and the first electrode layer ITO1 may be the first electrode 131.

Since the current injection area of the second electrode 135 is a current expansion area, the second electrode 135 may be formed to have the second uneven pattern as in FIG. 1 in order to increase the current injection area.

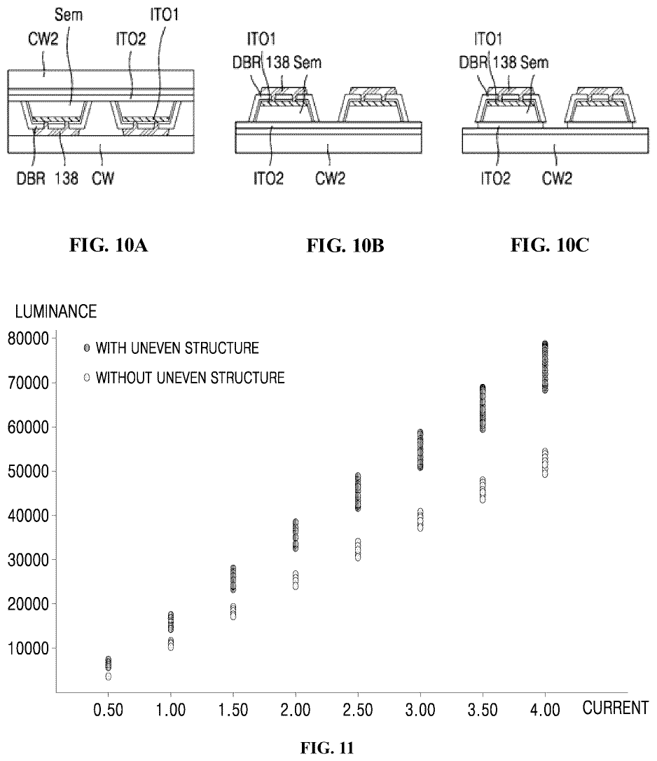

As the uneven structure is applied to the second electrode 135, it can be seen that the luminance of the corresponding light-emitting element is higher than that of a case in which the uneven structure is not applied as illustrated in FIG. 11. FIG. 11 is a graph illustrating luminance according to the amount of current when an uneven structure is applied to an electrode of the light-emitting element according to the embodiment of the present disclosure. In the light-emitting element according to the embodiment of the present disclosure, since the second electrode 135 has the uneven structure, the current injection area increases, and thus a luminance value also increases as the amount of the current increases.

In this case, the second semiconductor layer 134 corresponding to the second electrode 135 may be formed to have the first uneven pattern corresponding to the second uneven pattern.

In addition, the third uneven pattern may be formed on the upper surface of the second electrode 135 to correspond to the first uneven pattern and the second uneven pattern.

As described above, according to the embodiment of the present disclosure, it is possible to prevent the occurrence of a transfer defect due to a transfer error between the light-emitting element and the display panel during the transfer process.

In addition, according to the implementations of the present disclosure, the contact (current injection) area can be adjusted so that the bonding force between the light-emitting element and the transfer member is smaller than the bonding force between the light-emitting element and the panel during the transfer process.

A light-emitting element and a display device including the same according to an embodiment of the present disclosure may be described as follows.

According to an embodiment of the present disclosure, there is provided a light-emitting element including a first electrode, a first semiconductor layer disposed on the first electrode, an active layer disposed on the first semiconductor layer, a second semiconductor layer disposed on the active layer, and a second electrode disposed on the second semiconductor layer, in which a first uneven pattern is formed on an upper portion of the second semiconductor layer in contact with the second electrode, a second uneven pattern is formed on a lower portion of the second electrode corresponding to the first uneven pattern, and a third uneven pattern is formed on an upper portion of the second electrode.

According to some implementations of the present disclosure, each of the first uneven pattern, the second uneven pattern, and the third uneven pattern may be formed by alternating concave and convex shapes.

According to some implementations of the present disclosure, the light-emitting element may further include a first passivation layer disposed under the first electrode, a second passivation layer disposed under the first passivation layer, and a first bonding electrode disposed under the second passivation layer.

According to some implementations of the present disclosure, the first passivation layer may extend upward from both ends to surround outer edges of the first semiconductor layer, the active layer, and the second semiconductor layer, and the second passivation layer may extend upward from both ends to surround an outer edge of the first passivation layer.

According to some implementations of the present disclosure, the first bonding electrode may come into electrical contact with the first electrode through a plurality of through holes.

According to some implementations of the present disclosure, one of the first semiconductor layer and the second semiconductor layer may be a semiconductor layer doped with an N-type impurity, and the other may be a semiconductor layer doped with a P-type impurity.

According to some implementations of the present disclosure, the active layer may include a multi-quantum well (MQW) structure having a well layer and a barrier layer having a higher band gap than the well layer.

According to some implementations of the present disclosure, each of the first electrode and the second electrode may be formed of one of indium tin oxide (ITO), indium zinc oxide (IZO), and indium gallium zinc oxide (IGZO).

According to some implementations of the present disclosure, the first passivation layer and the second passivation layer may be formed of an insulation material including silicon nitride (SiNx) or silicon oxide (SiOx).

According to some implementations of the present disclosure, the first passivation layer and the second passivation layer may have a structure in which a reflective material is dispersed in a resin layer.

According to another embodiment of the present disclosure, there is provided a light-emitting element including a second electrode, a second semiconductor layer disposed on the second electrode, an active layer disposed on the second semiconductor layer, a first semiconductor layer disposed on the active layer, a first electrode disposed under one side of the first semiconductor layer, and a passivation layer surrounding outer edges of the second electrode, the second semiconductor layer, the active layer, the first semiconductor layer, and the first electrode, and the first semiconductor layer has an upper portion having an uneven pattern formed by alternating concave and convex shapes.

According to still another embodiment of the present disclosure, there is provided a display device including a plurality of light-emitting elements including a first electrode, a first semiconductor layer disposed on the first electrode, an active layer disposed on the first semiconductor layer, a second semiconductor layer disposed on the active layer, a second electrode disposed on the second semi conductor layer, a first passivation layer under the first electrode, a second passivation layer under the first passivation layer, and a first bonding electrode under the second passivation layer, the first bonding electrode coming into electrical contact with the first electrode through a plurality of through holes, a first uneven pattern being formed on an upper portion of the second semiconductor layer in contact with the second electrode, a second uneven pattern being formed on a lower portion of the second electrode corresponding to the first uneven pattern, and a third uneven pattern being formed on an upper portion of the second electrode, a second bonding electrode bonded to the first bonding electrode, a bank layer disposed under the second bonding electrode, a first connection electrode disposed on side surfaces and an upper surface of the bank layer and electrically connected to the second bonding electrode, a first optical layer surrounding the plurality of light-emitting elements, a second optical layer surrounding the first optical layer, a second connection electrode continuously extending and disposed on the first optical layer, the second optical layer, and the light-emitting elements, and a third optical layer disposed on the second connection electrode, in which the second connection electrode has a fourth uneven pattern that corresponds to the third uneven pattern and is formed at a portion in contact with the second electrode.

According to some implementations of the present disclosure, the display device may further include a driving chip disposed under the plurality of light-emitting elements, in which the driving chip may be electrically connected to each of the plurality of light-emitting elements.

According to some implementations of the present disclosure, in each of the plurality of light-emitting elements, the first electrode may be bonded to the first connection electrode by eutectic bonding of the first bonding electrode and the second bonding electrode.

According to some implementations of the present disclosure, each of the plurality of light-emitting elements may include a micro light-emitting diode (LED).

According to some implementations of the present disclosure, the plurality of light-emitting elements may include at least one of a first light-emitting element of a red color, a second light-emitting element of a green color, and a third light-emitting element of a blue color.

According to some implementations of the present disclosure, the first connection electrode may have a mirror shape in which a part of a surface in contact with the second connection electrode is removed or etched inward to expose an internal reflective material.

According to some implementations of the present disclosure, the first connection electrode may include a plurality of conductive layers, and the plurality of conductive layers may include a first conductive layer disposed on the bank layer, a second conductive layer disposed on the first conductive layer, a third conductive layer disposed on the second conductive layer, and a fourth conductive layer disposed on the third conductive layer.

According to some implementations of the present disclosure, the second conductive layer may include a reflective material.

According to some implementations of the present disclosure, when the second conductive layer is a reflector including the reflective material, parts of the third conductive layer and the fourth conductive layer may be removed or etched to expose an upper surface of the second conductive layer.

According to the implementations of the present disclosure, during the transfer process in which the transfer member picks up light-emitting elements, the electrostatic force between the light-emitting element and the transfer member can act more strongly than the bonding force between the light-emitting element and the donor member due to the uneven pattern formed on the upper surface of the light-emitting element, thereby preventing a transfer defect.

In addition, according to the implementations of the present disclosure, during the transfer process in which the transfer member is placed on the display panel, the van der Waals' force between the light-emitting element and the transfer member can act smaller than the bonding force between the light-emitting element and the display panel due to the uneven pattern formed on the upper surface of the light-emitting element, thereby preventing a transfer defect of the panel.

In addition, according to the implementations of the present disclosure, since the current injection area can be greater than those of the conventional models by the uneven pattern formed on the upper surface of each light-emitting element, it is possible to expand the light-emitting area, thereby increasing luminance.

In addition, according to the implementations of the present disclosure, since the current injection area can be greater than those of the conventional models by the uneven pattern formed on the upper surface of each light-emitting element, it is possible to increase luminous efficiency.

In addition, according to the implementations of the present disclosure, it is possible to have the optimal bonding force during the transfer process by the uneven pattern formed on the upper surface of each light-emitting element, thereby securing a transfer process margin.

In addition, according to the implementations of the present disclosure, it is possible to prevent damage to light-emitting elements or a panel defect by the uneven pattern formed on the upper surface of each light-emitting element during the transfer process, thereby improving the quality of the display device.

In addition, according to the implementations of the present disclosure, it is possible to improve the defect of the display panel, thereby preventing a reduction in life of the panel.

In addition, according to the implementations of the present disclosure, by preventing a panel defect so that the display panel operates without any failure, it is possible to provide a long-life and low-power display device.

Effects of the present disclosure are not limited to the above-described effects, and other effects that are not described will be able to be clearly understood by those skilled in the art based on the following description.

Specific effects of the present disclosure along with the above-described effects are described along with the description of the following detailed matters for carrying out implementations of the disclosure.

Although the present disclosure has been described above with reference to the exemplary drawings, the present disclosure is not limited by the implementations and drawings disclosed in the present disclosure, and it is apparent that various modifications can be made by those skilled in the art within the scope of the technical spirit of the present disclosure. In addition, even when the operational effects according to the configuration of the present disclosure have not been explicitly described in the description of the implementations of the present disclosure, it is apparent that the effects predictable by the corresponding configuration should also be recognized.

DESCRIPTION OF REFERENCE NUMERALS

| | |
|---|---|
| 100: display device | 10: donor member |
| 20: transfer member | 21: base layer |
| 22: stamp layer | 30: display panel |
| 130, 140, 150, ED: light-emitting element | |
| 131: first electrode | |
| 132, 134: semiconductor layer | 133: active layer |
| 135: second electrode | |
| 136, 137, PAS: passivation layer | |
| 138: first bonding electrode | |
| SDP: second bonding electrode | |
| CE1, CE2: connection electrode | BNK: bank layer |
| EA: light-emitting part | ENC: encapsulation layer |

What is claimed is:

1. A light-emitting element comprising:
a first electrode;
a first semiconductor layer on the first electrode;
an active layer on the first semiconductor layer;
a second semiconductor layer on the active layer; and
a second electrode on the second semiconductor layer,
wherein a first uneven pattern is on an upper portion of the second semiconductor layer in contact with the second electrode, a second uneven pattern is on a lower portion of the second electrode corresponding to the first uneven pattern, and a third uneven pattern is on an upper portion of the second electrode.

2. The light-emitting element of claim 1, wherein each of the first uneven pattern, the second uneven pattern, and the third uneven pattern includes an alternating concave shape and convex shape.

3. The light-emitting element of claim 1, further comprising:
a first passivation layer under the first electrode;
a second passivation layer under the first passivation layer; and
a first bonding electrode under the second passivation layer.

4. The light-emitting element of claim 3, wherein the first passivation layer extends upward from both ends and surrounds outer edges of the first semiconductor layer, the active layer, and the second semiconductor layer, and the second passivation layer extends upward from both ends and surround an outer edge of the first passivation layer.

5. The light-emitting element of claim 3, wherein the first bonding electrode is electrically connected to the first electrode via a plurality of through holes.

6. The light-emitting element of claim 1, wherein one of the first semiconductor layer and the second semiconductor layer is a semiconductor layer doped with an N-type impurity, and another of the first semiconductor layer and the second semiconductor layer is a semiconductor layer doped with a P-type impurity.

7. The light-emitting element of claim 1, wherein the active layer includes a well layer and a multi-quantum well (MQW) structure having a barrier layer having a higher band gap than the well layer.

8. The light-emitting element of claim 1, wherein each of the first electrode and the second electrode includes one of indium tin oxide (ITO), indium zinc oxide (IZO), and indium gallium zinc oxide (IGZO).

9. The light-emitting element of claim 3, wherein the first passivation layer and the second passivation layer comprise an insulation material including silicon nitride (SiNx) or silicon oxide (SiOx).

10. The light-emitting element of claim 3, wherein the first passivation layer and the second passivation layer have a structure in which a reflective material is dispersed in a resin layer.

11. A light-emitting element comprising:
a second electrode;
a second semiconductor layer on the second electrode;
an active layer on the second semiconductor layer;
a first semiconductor layer on the active layer;
a first electrode under one side of the first semiconductor layer; and
a passivation layer that surrounds outer edges of the second electrode, the second semiconductor layer, the active layer, the first semiconductor layer, and the first electrode,
wherein the first semiconductor layer has an upper portion having an uneven pattern including an alternating concave shape and convex shape.

12. A display device comprising:
a plurality of light-emitting elements including a first electrode, a first semiconductor layer on the first electrode, an active layer disposed on the first semiconductor layer, a second semiconductor layer on the active layer, a second electrode on the second semiconductor layer, a first passivation layer under the first electrode, a second passivation layer under the first passivation layer, and a first bonding electrode under the second passivation layer, the first bonding electrode is electrically connected to the first electrode via a plurality of through holes, a first uneven pattern on an upper portion of the second semiconductor layer in contact with the second electrode, a second uneven pattern on a lower portion of the second electrode corresponding to the first uneven pattern, and a third uneven pattern on an upper portion of the second electrode;
a second bonding electrode bonded to the first bonding electrode;
a bank layer under the second bonding electrode;
a first connection electrode on side surfaces and an upper surface of the bank layer, the first connection electrode electrically connected to the second bonding electrode;
a first optical layer surrounding the plurality of light-emitting elements;
a second optical layer surrounding the first optical layer;
a second connection electrode that continuously extends on the first optical layer, the second optical layer, and a light-emitting element from the plurality of light-emitting elements; and
a third optical layer on the second connection electrode,
wherein the second connection electrode has a fourth uneven pattern that corresponds to the third uneven pattern and is location at a portion in contact with the second electrode.

13. The display device of claim 12, further comprising:
a driving chip under the plurality of light-emitting elements, the driving chip electrically connected to each of the plurality of light-emitting elements.

14. The display device of claim 12, wherein, in each of the plurality of light-emitting elements, the first electrode is bonded to the first connection electrode by eutectic bonding of the first bonding electrode and the second bonding electrode.

15. The display device of claim 12, wherein each of the plurality of light-emitting elements includes a micro light-emitting diode.

16. The display device of claim 15, wherein the plurality of light-emitting elements include at least one of a first light-emitting element of a red color, a second light-emitting element of a green color, and a third light-emitting element of a blue color.

17. The display device of claim 12, wherein the first connection electrode has a mirror shape in which a part of a surface in contact with the second bonding electrode is removed or etched inward to expose an internal reflective material.

18. The display device of claim 17, wherein the first connection electrode includes a plurality of conductive layers, and the plurality of conductive layers include:
a first conductive layer on the bank layer;
a second conductive layer on the first conductive layer;
a third conductive layer on the second conductive layer; and
a fourth conductive layer on the third conductive layer.

19. The display device of claim 18, wherein the second conductive layer includes a reflective material.

20. The display device of claim 19, wherein the second conductive layer is a reflector including the reflective material and parts of the third conductive layer and the fourth conductive layer are removed or etched to expose an upper surface of the second conductive layer.
